(19) United States
(12) Patent Application Publication
(10) Pub. No.: US 2015/0274517 A1
(43) Pub. Date: Oct. 1, 2015

(54) METHOD TO IMPROVE SURFACE ROUGHNESS AND ELIMINATE SHARP CORNERS ON AN ACTUATOR LAYER OF A MEMS DEVICE

(71) Applicant: InvenSense, Inc., San Jose, CA (US)

(72) Inventors: Peter SMEYS, San Jose, CA (US); Jongwoo SHIN, Pleasanton, CA (US); Jong Il SHIN, San Jose, CA (US)

(21) Appl. No.: 14/453,431

(22) Filed: Aug. 6, 2014

Related U.S. Application Data
(63) Continuation-in-part of application No. 14/225,275, filed on Mar. 25, 2014.
(60) Provisional application No. 62/000,418, filed on May 19, 2014.

(51) Int. Cl. B81C 1/00

(52) U.S. Cl. CPC B81C 1/00626; B81C 2201/0169

(57) ABSTRACT

A method for forming an actuator layer of a MEMS device is disclosed. The method comprising etching the actuator layer and annealing the actuator layer after etching to reduce surface roughness of the MEMS device.

### CROSS-REFERENCE TO RELATED APPLICATION

This application claims benefit under 35 USC 119(e) of U.S. Provisional Patent Application No. 62/000,418, filed on May 19, 2014, entitled “METHOD TO IMPROVE SURFACE ROUGHNESS AND ELIMINATE SHARP CORNERS ON AN ACCELEROMETER OR GYRO ACTUATOR,” and is a continuation-in-part of U.S. patent application Ser. No. 14/225,275, filed Mar. 25, 2014, entitled “REDUCTION OF CHIPPING DAMAGE TO MEMS STRUCTURE,” (Attorney Docket No. IVS-217/5331P) all of which are incorporated herein by reference in their entireties.

### FIELD OF THE INVENTION

The present invention relates generally to the fabrication of MEMS (Microelectromechanical systems) devices and more particularly providing for rounded corners and/or minimizing scalloping on MEMS substrates.

### BACKGROUND OF THE INVENTION

MEMS devices are utilized in a variety of environments. MEMS devices may encounter damage, such as chipping, typically induced by mechanical shock as structures bump into one another depending on their arrangement.

A MEMS structure is situated near a current sidewall profile of a MEMS device. Typically chipping damage is induced by the structures bumping with one another due to mechanical shock. It will be appreciated by those skilled in the art that chipping damage may occur where two structures make contact with each other when mechanical shock is applied and can be found from an actuator layer surface facing a second substrate. It will be further appreciated that chipping damage may often be more problematic on the side that is facing for example a substrate because chipped silicon pieces may fall on to the metal electrodes on the substrate and create the opportunity for electrical shorts between electrodes that intended to be isolated.

Unfortunately, with ever-increasing density demands for chip placement in circuitry, the potential for chipping damage and electrical short situations are increasing such that increasing dimensional placement between devices is not a viable option. What is therefore desired is a device and method that overcomes these challenges and provides for arranging MEMS in proximity to one another, in densely-packed arrangements, with unique sidewall or substrate configurations that reduce the likelihood of chipping and electrical shorting.

### SUMMARY OF THE INVENTION

The present invention fulfills these needs and has been developed in response to the present state of the art, and in particular, in response to the problems and needs in the art that have not yet been fully solved by currently available technologies.

One embodiment of the present invention provides a method for forming an actuator layer of a MEMS device comprising etching the actuator layer; and annealing the actuator layer after etching to reduce surface roughness of the MEMS device.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1A shows cross-sectional view of a MEMS device after a deep reactive ion etch (DIRE).

FIG. 1B shows cross-sectional view of a MEMS device a high temperature anneal.

FIG. 1C shows a close up profile of the actuator layer in accordance with an embodiment.

### DETAILED DESCRIPTION

The present invention relates generally to the fabrication of MEMS (Microelectromechanical systems) devices and more particularly providing for rounded corners and/or minimizing scalloping on MEMS substrates.

The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiment shown but is to be accorded the widest scope consistent with the principles and features described herein.

In the described embodiments micro-electro-mechanical systems (MEMS) refers to a class of structures or devices fabricated using semiconductor-like processes and exhibiting mechanical characteristics such as the ability to move or deform. In the described embodiments, the MEMS device may refer to a semiconductor device implemented as a micro-electro-mechanical system. The MEMS structure may refer to any feature that may be part of a larger MEMS device. MEMS devices often, but not always, interact with electrical signals. MEMS devices include but are not limited to gyroscopes, accelerometers, magnetometers, pressure sensors, microphones, and radio-frequency components. Silicon wafers containing MEMS structures are referred to as MEMS wafers.

A structural layer may refer to the silicon layer with moveable structures. An engineered silicon-on-insulator (ESOI) wafer may refer to an SOI wafer with cavities beneath the silicon structural layer. A cap wafer typically refers to a thicker substrate used as a carrier for the thinner silicon device substrate in a silicon-on-insulator wafer.

A MEMS substrate provides mechanical support for the MEMS structure. The MEMS structural layer is attached to the MEMS substrate. The MEMS substrate is also referred to as handle substrate or handle wafer. In some embodiments, the handle substrate serves as a cap to the MEMS structure. A cap or a cover provides mechanical protection to the structural layer and optionally forms a portion of the enclosure. Standoff defines the vertical clearance between the structural layer and the IC substrate.

Standoff may also provide electrical contact between the structural layer and the IC substrate. Standoff may also provide a seal that defines an enclosure. Integrated Circuit (IC) substrate may refer to a silicon substrate with electrical circuits, typically CMOS circuits. A cavity may refer to a recess in a substrate. Chip includes at least one substrate typically formed from a semiconductor material. A single chip may be formed from multiple substrates, where the substrates are mechanically bonded together. Multiple chip includes at least 2 substrates, wherein the 2 substrates are electrically connected, but do not require mechanical bonding.

An actuator layer etch process of a MEMS device comprises cycles of etch and sidewall passivation. Owing to this cyclic etch and passivation process, the sidewall tends to have peaks and valleys or so called ‘scallops’. If there are sharp peaks at the scallop, in-plane movement of an actuator layer can cause small particles due to the impact of two adjacent MEMS surfaces.

One of the challenges in a MEMS device is breakage induced by in-plane and/or out-of plane movement of the actuator layer. In-plane movement of the actuator layer causes friction between two surfaces and therefore may result in scallops. Furthermore, out of plane movement of the actuator layer at a tilted angle can lead to relatively larger chipping along sharp corners of the actuator layer. Having a MEMS directly integrated onto CMOS substrate, the chipping and/or particles can result in CMOS circuit short leading to device failure(s).

Applicants have addressed the issue of scallops and sharp corners in U.S. patent application Ser. No. 14/225,275, filed Mar. 25, 2014, entitled “REDUCTION OF CHIPPING DAMAGE TO MEMS STRUCTURE,” (Attorney Docket No. IVS-217/5331P) assigned to the assignee of the present application which is incorporated by reference in the present specification. Although the techniques disclosed in the above identified application are effective, different and improved methods to address the problem of scallops and sharp corners on the surface of the actuator layer are desired.

In a method in accordance with an embodiment, a surface of a MEMS device is annealed at high temperature in hydrogen ambient which increases silicon atom ion mobility on the surface. Advantages of applying a high temperature anneal are removal of scallops and sharp corners on the surface of the MEMS device. A method in accordance with an embodiment reduces particles on the surface generated by in-plane friction and reduces chipping that occurs during out of plane movement of the actuator layer due to the rounded corners thereon. To describe the features of the present invention in more detail refer now to the following description in conjunction with the accompanying Figures.

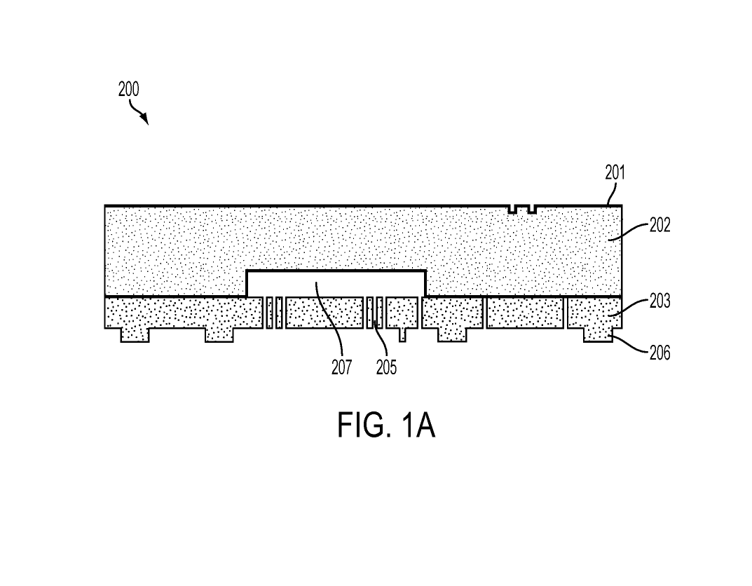

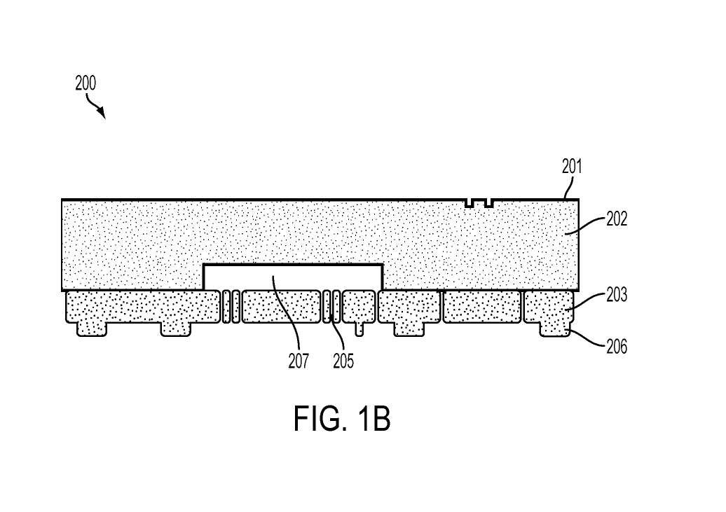

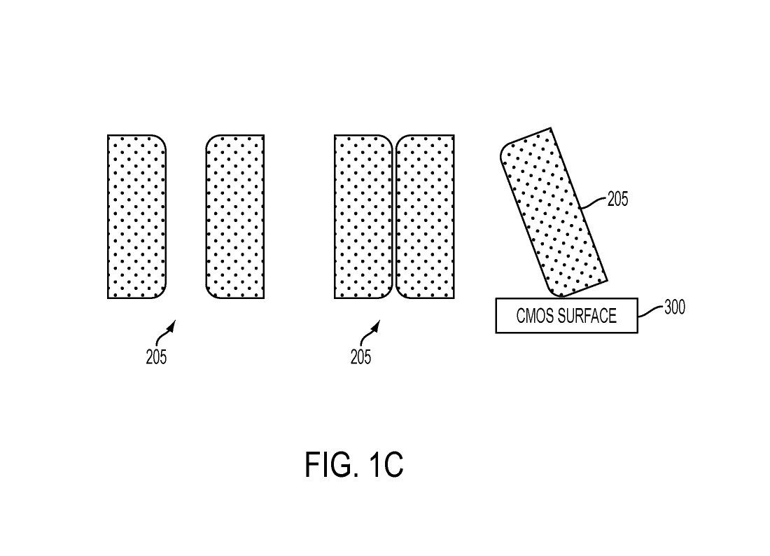

FIG. 1A shows cross-sectional view of a MEMS device 200 after a first deep reactive ion etch (DRE). The MEMS device 200 comprises a MEMS substrate 203 coupled to a MEMS handle wafer 202. In this embodiment the handle wafer includes an oxide layer 201 on a top surface thereof. The MEMS device 200 also includes an upper cavity 207 and a MEMS bond anchor or standoff 206. The MEMS substrate 203 also includes an actuator layer 205 which is patterned by the DRE as shown in FIG. 1B.

A subsequent high temperature anneal will provide smooth surfaces and rounded corners for the actuator layer 205. What is meant by a high temperature anneal in the context of a hydrogen environment is a temperature of 1000 degrees C. or greater. What is meant by rounded corners are corners with a radius of curvature that is greater than or equal to 0.2 um.

FIG. 1C shows a close up profile of the actuator layer 205 in accordance with an embodiment. As shown FIG. 1C, scallops are minimized and rounded corners are provided against a CMOS surface 300 based upon the above identified process. Accordingly, by applying a high temperature anneal scallops and sharp corners on the surface of the MEMS device are substantially reduced.

In the described embodiments, the device can be any MEMS device or sensor with a moveable structure such as but not limited to accelerometer, gyroscope, magnetic sensors and resonators. In the described embodiments, the IC substrate can include electronic circuits for sensing and processing the motion of the MEMS device, without limitation. One skilled in the art would appreciate that the IC substrate 920 can be substituted with any type of substrate such as a ceramic substrate or a silicon substrate.

Any theory, mechanism of operation, proof, or finding stated herein is meant to further enhance understanding of the present invention and is not intended to make the present invention in any way dependent upon such theory, mechanism of operation, proof, or finding. It should be understood that while the use of the words preferable, preferably, or preferred in the description above indicates that the feature so described may be more desirable, it nonetheless may not be necessary and embodiments lacking the same may be contemplated as within the scope of the invention, that scope being defined by the claims that follow.

Although the present invention has been described in accordance with the embodiments shown, one of ordinary skill in the art will readily recognize that there could be variations to the embodiments and those variations would be within the spirit and scope of the present invention, such as the inclusion of circuits, electronic devices, control systems, and other electronic and processing equipment. Accordingly, many modifications may be made by one of ordinary skill in the art without departing from the spirit and scope of the appended claims. Many other embodiments of the present invention are also envisioned.

What is claimed is:

1. A method for forming an actuator layer of a MEMS device comprising:
etching the actuator layer; and
annealing the actuator layer after etching to reduce surface roughness of the MEMS device.

2. The method of claim 1, wherein the annealing reduces scallops.

3. The method of claim 1, wherein the annealing produces rounded corners.

4. The method of claim 1, wherein the annealing comprises hydrogen annealing.

5. The method of claim 1, wherein the annealing is performed at a temperature greater than 1000C.

6. The method of claim 1, wherein the MEMS device comprises a MEMS sensor.
